(19) United States
(12) Patent Application Publication
(10) Pub. No.: US 2024/0399953 A1
(43) Pub. Date: Dec. 5, 2024

(54) OPERATING ELEMENT FOR A VEHICLE INTERIOR

(71) Applicant: Faurecia Innenraum Systeme GmbH, Hagenbach (DE)

(72) Inventors: Julien BEAUREGARD, Le Mesnil En Thelle (FR); Ruddy CITTADINI, Landau (DE)

(73) Assignee: Faurecia Innenraum Systeme GmbH, Hagenbach (DE)

(21) Appl. No.: 18/678,745

(22) Filed: May 30, 2024

(30) Foreign Application Priority Data
May 31, 2023 (DE) 202023102992.2

(51) Int. Cl. B60Q 3/82; B60K 35/22; B60Q 3/54; G06F 3/01

(52) U.S. Cl. CPC B60Q 3/82; B60K 35/22; B60Q 3/54; G06F 3/016

(57) ABSTRACT

The invention concerns an operating element (100, 100′, 100″) for a vehicle interior, comprising
an at least partially transparent cover layer (200) having at least one tactilely detectable raised and/or recessed area (210) on an upper side (201) of the cover layer (200) facing the vehicle interior,
a light source (300) configured to emit light toward an underside (202) of the cover layer (200) opposite the upper side (201),
a non-transparent mask layer (400) arranged between the light source (300) and at least a portion of the cover layer (200), and
an actuating element (500), that can be activated by touching the upper side (201) of the transparent cover layer (200), configured to output an operating signal when activating the actuating element (500).

The application relates to an operating element for a vehicle interior.

Numerous operating elements for vehicle interiors are known from the prior art. Reconfigurable operating elements are increasingly being used, in which context-dependent operating symbols are displayed on a user interface using a light source and/or a display element. In contrast to traditional mechanical operating elements, for example pushbuttons, rocker switches, slide controls, etc., detecting the operating areas of a reconfigurable operating element is often only possible visually, but not through tactile perception. As a result, more difficult operation and/or distractions can occur during travel. On the other hand, known tactilely detectable operating elements are often not reconfigured, in particular not visually reconfigurable. In principle, it is also desirable that operating elements, due to the requirements in vehicles, can be produced in a compact, decorative, robust, durable, simple and cost-efficient manner and are designed to be easily operable.

Against the background of the prior art, the application is based on the object of proposing an operating element which has one or more of the mentioned properties or reduces or avoids the mentioned problems.

To solve the problem, an operating element according to claim 1 is proposed. Advantageous refinements and further developments arise in connection with the features of the subclaims.

The proposed operating element for a vehicle interior comprises:
an at least partially transparent cover layer having at least one tactilely detectable raised and/or recessed area on an upper side of the cover layer facing the vehicle interior,
a light source configured to emit light in the direction of an underside of the cover layer opposite the upper side,
a non-transparent mask layer arranged between the light source and at least a portion of the cover layer, and
an actuating element that can be activated by touching the upper side of the transparent cover layer, configured to output an operating signal when the actuating element is activated.

The at least one tactilely detectable raised and/or recessed area can enable or facilitate tactile detection of an operating area or several operating areas of the operating element. A reconfigurable operating element with easy operability can thus be ensured. Distractions can be avoided or reduced by visually recording the operating areas. In addition, the operating areas can be arranged in a particularly tight manner together by means of their tactile ability to detect and/or be provided in reduced size, so that a compact design of the operating element can be made possible. The transparent cover layer also enables a particularly robust and long-lasting design of the operating element. The construction, in particular the layer structure, of the operating element is suitable for simple and cost-effective production methods.

The operating element can comprise several tactilely detectable raised and/or recessed areas on the upper side of the cover layer facing the vehicle interior. In this way, a more complex arrangement of tactilely detectable operating areas can be possible. The raised and/or recessed area can, for example, comprise a, for example round or polygonal, central elevation and/or depression and a plurality of, for example elongated, elevations and/or recesses for dividing the operating element into several of operating areas in a tactile detectable manner.

The connection of the transparent cover layer and the non-transparent mask layer can provide a visually appealing/decorative appearance, for example even in an inactive state of the operating element in which the light source is switched off. The raised and/or recessed area itself can also develop particularly decorative effects by its 3D shape design. The cover layer with the at least one tactilely detectable raised and/or recessed area can be formed in the manner of a 3D shaped lens.

One or more operating areas of the operating element can be visible, in particular visually reconfigurable, by a light emitted by the light source, and can be operated by means of the actuating element. The mask layer can thereby cover areas which are not illuminated by the light source (and thus, in particular, not made visible as an operating area). The mask layer can simultaneously act as a support or carrier layer of the cover layer or vice versa.

The mask layer can accordingly cover at least a portion of the cover layer. The mask layer can at least partially cover the raised and/or recessed area of the cover layer. The mask layer cannot cover an area of the cover layer surrounding the raised and/or recessed area. In such embodiments, the raised and/or recessed area can in particular make an operating area surrounding it or an operating area arranged in the surrounding area tactilely detectable without itself being part of the operating area. Alternatively, the mask layer cannot at least partially cover the raised and/or recessed area. The raised and/or recessed area can at least partially comprise an operating area.

The mask layer can comprise at least one recess for transmitting the light emitted by the light source to the cover layer. The actuating element can be operable in the area of the at least one recess.

The upper side of the cover layer can comprise tactilely detectable areas of different surface properties, in particular different surface roughness. The tactile detectability can thereby be improved, in particular in order to supplement a haptic quality. An increased surface roughness can be provided, for example, by sandblasting and/or a paint application.

The cover layer can be manufactured by means of an injection molding process. The mask layer can be manufactured by means of an injection molding process. The cover layer can rest against the mask layer without an intermediate air gap. The cover layer can be integrally bonded to the mask layer. The cover layer can be integrally formed with the mask layer. The cover layer can be applied to the mask layer by overmolding. The mask layer can be applied to the cover layer by back-injection. Particularly simple and cost-effective possibilities for producing the operating element are thereby provided.

The actuating element can be or comprise a capacitive actuating layer. A particularly simple operation and reconfigurable arrangement of operating areas can thus be enabled. The capacitive actuating layer is preferably transparent for transmitting the light from the light source.

The mask layer can be connected to the actuating element by means of a first transparent adhesive layer. The first transparent adhesive layer can comprise an optically clear adhesive film. The first transparent adhesive layer can comprise an optically clear liquid adhesive (LOCA).

The actuating element can be connected to the light source by means of a second transparent adhesive layer. The second transparent adhesive layer can comprise an optically clear adhesive film. The second transparent adhesive layer may comprise an optically clear liquid adhesive (LOCA).

The operating element may comprise a haptic actuator configured to generate a vibration when the actuating element is actuated. The haptic actuator is preferably arranged on a rear side of the light source facing away from the cover layer. The haptic actuator may alternatively be arranged, for example, on a rear side of the mask layer facing away from the cover layer. The haptic actuator may comprise a voice coil type actuator. The haptic actuator may comprise a cylinder coil type actuator. The haptic actuator may generate haptic feedback during operation and thus enable a particularly simple and comfortable operation. For example, after emitting the vibration, the operating element can be reconfigured in order to display and/or operate a submenu of a previously operated menu.

The cover layer may comprise a polyurethane material. The mask layer may comprise a polypropylene material. The mask layer may comprise a polycarbonate Material. The mask layer may comprise a polycarbonate-acrylonitrile-butadiene-styrene material. The mask layer may comprise a polyurethane material. The materials or material combinations mentioned can ensure particularly simple and cost-effective production and/or a robust and long-lasting design of the operating element. Other materials, in particular plastic materials, or material combinations can also be provided. The cover layer may comprise a glass material, in particular a cured glass material.

The operating element may comprise color adjustment layer with a gray film and/or a color film. The color matching layer may be arranged between the mask layer and the light source. The color matching layer may be arranged between the mask layer and the first transparent adhesive layer. By means of the color adjustment layer, color differences and/or brightness differences and/or different surface properties of the various components of the operating element, in particular between the mask layer and underlying components such as the light source and/or the capacitive actuation layer, can be compensated for.

The light source may comprise a segmented and/or spatially resolved display. In this way, for example, different reconfigurable operating symbols can be displayed. The light source can comprise an LCD display and/or a TFT display and/or an OLED display and/or an LED matrix display and/or a MicroLED display.

The operating element may furthermore comprise a pressure sensor. The pressure sensor can be arranged on a rear side of the light source facing away from the cover layer. The pressure sensor can in particular be provided in addition to the capacitive actuating layer. The pressure sensor can be arranged between the light source and the haptic actuator. By combining the pressure sensor with the capacitive actuating layer, incorrect operations, for example by placing a palm and/or a heel of a hand on the operating element, can be avoided.

If a single pressure sensor is provided, this may advantageously be arranged centrally below a display area of the light source. The operating element may comprise a plurality of pressure sensors, which are arranged in particular at corners of a display area of the light source.

The operating element may comprise the following components in a stacked arrangement according to the following order:
the cover layer,
the mask layer,
a first transparent adhesive layer by means of which the mask layer is connected to the actuating element,
the actuating element, comprising or designed as a transparent capacitive actuating layer, a second transparent adhesive layer by means of which the actuating element is connected to the light source,
the light source, and
a haptic actuator configured to generate a vibration when the actuating element is actuated.

The mentioned selection and arrangement of the components can enable a particularly advantageous, in particular robust, compact and/or simple/cost-effective design of the operating element.

Exemplary embodiments of the subject matter of the application are explained below with reference to drawings. In each case they show, schematically,

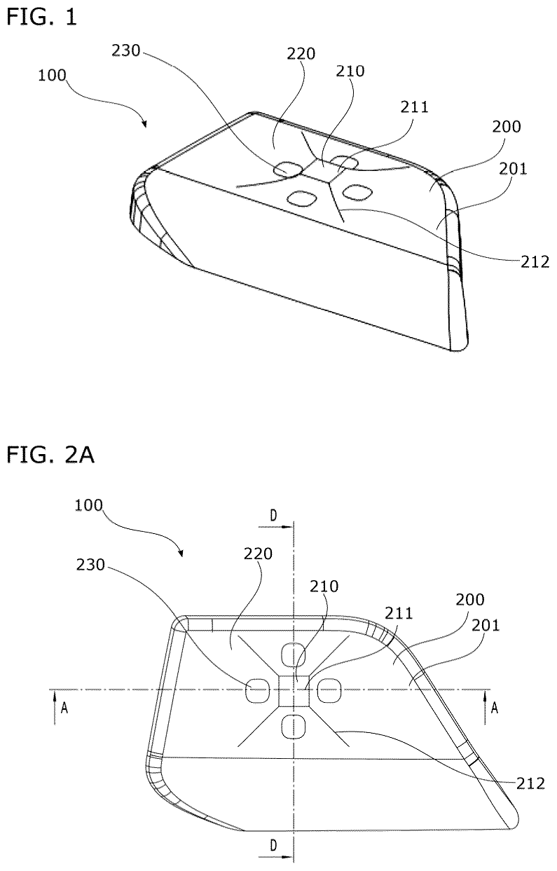

FIG. 1 is a perspective view of an operating element,

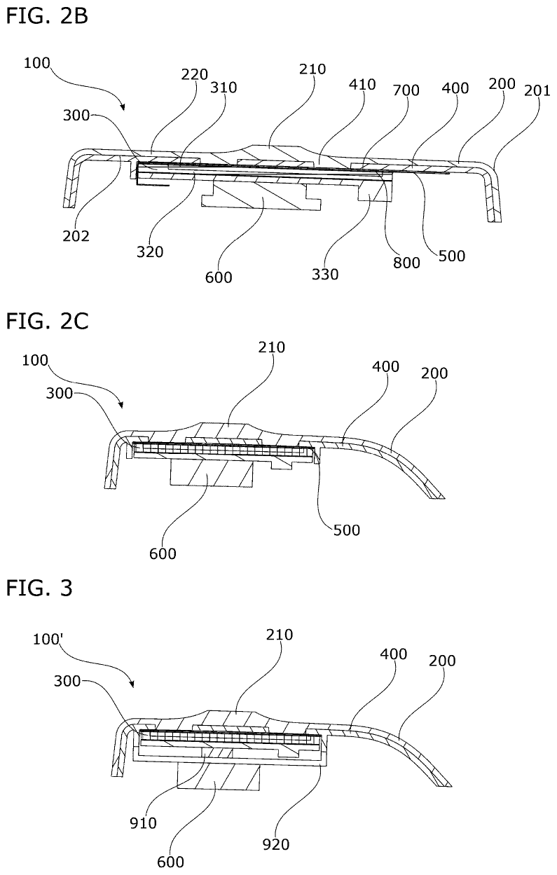

FIG. 2A shows the operating element according to FIG. 1 in a plan view,

FIG. 2B is a longitudinal section through the operating element according to FIG. 1 along the section A-A shown in FIG. 1,

FIG. 2C is a cross section through the operating element according to FIG. 1 along the section D-D shown in FIG. 1,

FIG. 3 is a cross section through an operating element according to a further embodiment,

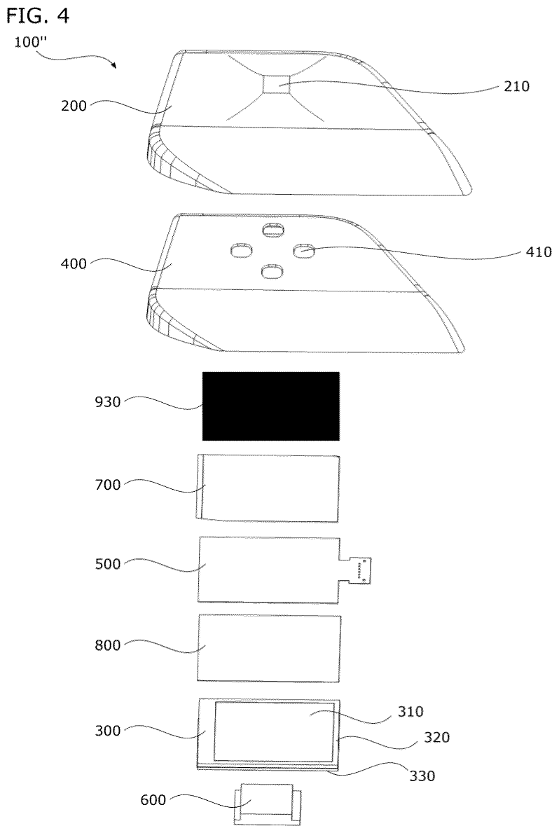

FIG. 4 is an exploded view of an operating element according to a further example.

Recurring and similar features are provided with identical alphanumeric reference signs in the drawings. Reference signs shown in other drawings are partially omitted.

The operating element 100 for a vehicle interior shown in FIGS. 1 and 2A to 2C comprises:
an at least partially transparent cover layer 100 having a tactilely detectable raised area 210 on an upper side 201 of the cover layer that faces the vehicle interior during normal operation,
a light source 300 configured to emit light in the direction of an underside 202 of the cover layer 200 opposite the upper side 201,
a non-transparent mask layer 400 arranged between the light source 300 and at least a portion of the cover layer 100, and
an actuating element 500 that can be activated by touching the upper side 201 of the transparent cover layer, configured to output an operating signal when activating the actuating element 500. Different functions of the vehicle can be controlled by means of the output operating signal.

The raised area 210 comprises a central elevation 211 and a plurality of elongated web areas 212 originating therefrom, which divide the operating element 100 into a plurality of operating areas 230 which can be detected in a tactile manner. The cover layer 200 with the raised area 210 is formed in the manner of a 3D shaped lens. Alternatively or in addition to the raised area 210, a recessed region can be provided. The operating element 100 may comprise a plurality of tactilely detectable raised and/or recessed areas on the upper side 201 of the cover layer 202 facing the vehicle interior.

The operating areas 230 of the operating element 100 can be made visible by a light emitted by the light source, wherein the light source comprises a spatially resolved display element 310 in the form of a segmented, spatially resolved display for displaying different operating symbols (and thus reconfigurable). The display element 310 may comprise, for example, an LCD display and/or a TFT display and/or an OLED display and/or an LED Matrix display and/or a MicroLED display. The light source 300 further comprises a printed circuit board 320 for controlling the display element 310. The light source 310 is arranged on a rigid carrier 330. The carrier 330 may be omitted in some examples.

The operating areas 230 can be operated by actuating underlying regions of the actuating element 500. In this case, the mask layer 400 covers areas which are not to be illuminated by the light source 300. The mask layer 400 simultaneously acts as a support or support carrier layer of the cover layer 200.

The mask layer 400 accordingly covers a part of the cover layer 200 (on its underside 202). The mask layer 400 specifically covers a large part of the raised area 210 of the cover layer 200. The mask layer does not cover an surrounding area 220 of the cover layer 200 surrounding the raised area 210. The raised area 210 thus makes the operating areas 230 arranged in the surrounding area 220 tactile, without itself being part of the operating areas 230. The raised area 210 may alternatively itself be part of one or more operating areas 230 and in this way make the corresponding operating areas 230 tactilely detectable.

The mask layer 400 has recesses 410 for allowing the light emitted by the light source 300 to pass through to the cover layer 200. The actuating element 500 may be actuated in the area of the recesses 410.

The upper side 201 of the cover layer 200 may comprise tactilely detectable regions of different surface properties, in particular different surface roughness. For example, the central elevation 211 may have a surface roughened by sandblasting.

The cover layer 200 and the mask layer 400 are integrally manufactured by means of an injection molding method. The cover layer 200 is integrally formed with the mask layer 400 in that the cover layer 200 is applied to the mask layer 400 by overmolding, or the mask layer 400 is applied to the cover layer 200 by back-injection. The cover layer 200 thus rests against the mask layer 400 without an intermediate air gap. The cover layer 200 comprises a polyurethane material. The mask layer 400 may comprise, for example, a polypropylene material or a polycarbonate material or a polycarbonate-acrylonitrile-butadiene-styrene material or also a polyurethane material. Other materials, in particular plastic materials, or material combinations can also be provided. The cover layer 200 may comprise a glass material, in particular a cured glass material.

The actuating element 500 is a capacitive actuating layer which is transparent to allow the light from the light source 300 to pass through.

The operating element 100 comprises a haptic actuator 600, configured to generate a vibration when the actuating element 500 is actuated in the area of one of the operating areas 230. The haptic actuator 600 is arranged on a rear side of the carrier 330 of the light source 300 facing away from the cover layer 200. The haptic actuator 600 preferably comprises a vibration damper, but may also comprise a cylinder plunger, for example. The haptic actuator 600 generates haptic feedback when operating the operating element 100. The haptic actuator 600 may alternatively be arranged, for example, on a rear side of the mask layer 400 facing away from the cover layer 200.

The mask layer is connected to the actuating element 500 by means of a first transparent adhesive layer 700. The first transparent adhesive layer 700 comprises an optically clear liquid adhesive (LOCA). The first transparent adhesive layer 700 may alternatively comprise an optically clear adhesive film

The actuating element 500 is connected to the light source 300 by means of a second transparent adhesive layer 800. The second transparent adhesive layer 800 comprises an optically clear liquid adhesive (LOCA). The second transparent adhesive layer 800 may comprise an optically clear adhesive film.

The operating element 100 comprises the following components in a directly stacked arrangement according to the following order: the cover layer 200, the mask layer 400, the first transparent adhesive layer 700, the actuating element 500, the second transparent adhesive layer 800, the light source 300, and the haptic actuator 600.

The operating element 100′ shown in FIG. 3 is substantially identical to the previously described operating element 100, but additionally comprises a pressure sensor 910. The pressure sensor 910 is arranged on the rear side of the carrier 330 of the light source 300, i.e. between the light source 300 and the haptic actuator 600. The haptic actuator is supported by a transmission element 920, wherein the transmission element 920 is configured to transmit vibrations of the haptic actuator 600. By combining the pressure sensor 910 with the capacitive actuating layer of the actuating element 500, incorrect operations, for example by placing a palm and/or a heel of a hand on the operating element 100, can be avoided.

In the example shown, a single pressure sensor 910 is provided. The latter is arranged centrally under the display element 310 of the light source 300 forming a display region. The operating element 100 may comprise a plurality of pressure sensors which are arranged in particular at corners of the display area of the light source 300.

The operating element 100′ shown in FIG. 4 is substantially identical to the previously described operating element 100, but additionally comprises a color adaptation layer 930 in the form of a colored film (color film). Alternatively or additionally, a gray film can be provided. The color matching layer 930 is arranged between the mask layer 400 and the light source 300, more precisely between the mask layer 400 and the first transparent adhesive layer 700. By means of the color matching layer 930, color differences and/or brightness differences and/or different surface properties of the mask layer 400 and the underlying components, in particular the light source 300, are compensated.

In this example, the first transparent adhesive layer 700 and the second transparent adhesive layer 800 are optically clear adhesive films.

### LIST OF REFERENCE SIGNS

100, 100′, 100″ operating element,
200 cover layer,
201 upper side,
202 underside,
210 raised area,
211 central elevation,
212 web area,
220 surrounding area
230 operating area,
300 light source,
310 display element,
320 printed circuit board,
330 carrier,
400 mask layer,
410 recess,
500 actuating element,
600 haptic actuator,
700 first transparent adhesive layer,
800 second transparent adhesive layer,
910 pressure sensor,
920 transmission element,
930 color matching layer.

1. An operating element (100, 100′, 100″) for a vehicle interior, comprising
an at least partially transparent cover layer (200) having at least one tactilely detectable raised and/or recessed area (210) on an upper side (201) of the cover layer (200) facing the vehicle interior,
a light source (300) configured to emit light toward an underside (202) of the cover layer (200) opposite the upper side (201),
a non-transparent mask layer (400) arranged between the light source (300) and at least a portion of the cover layer (200), and
an actuating element (500), that can be activated by touching the upper side (201) of the transparent cover layer (200), configured to output an operating signal when activating the actuating element (500).

2. The operating element (100, 100′, 100″) according to claim 1, wherein the mask layer (400) covers at least a portion of the cover layer (200).

3. The operating element (100, 100′, 100″) according to claim 1, wherein the mask layer (400) at least partially covers the raised and/or recessed region (210) of the cover layer (200).

4. The operating element (100, 100′, 100″) according to claim 1, wherein the mask layer (400) does not cover a surrounding area (220) of the cover layer (200) surrounding the raised and/or recessed area (210).

5. The operating element (100, 100′, 100″) according to claim 1, wherein the mask layer (400) comprises at least one recess (410) for allowing the light emitted by the light source (300) to pass through to the cover layer (200).

6. The operating element (100, 100′, 100″) according to claim 5, wherein the actuating element (500) can be actuated in the area of the at least one recess (410).

7. The operating element (100, 100′, 100″) according to claim 1, wherein the upper side (201) of the cover layer (200) comprises tactilely detectable areas of different surface properties, in particular different surface roughness.

8. The operating element (100, 100′, 100″) according to claim 1, wherein the cover layer (200) is manufactured by means of an injection molding method.

9. The operating element (100, 100′, 100″) according to claim 1, wherein the mask layer (400) is manufactured by means of an injection molding method.

10. The operating element (100, 100′, 100″) according to claim 1, wherein the cover layer (200) rests against the mask layer (400) without an intermediate air gap.

11. The operating element (100, 100′, 100″) according to claim 1, wherein the cover layer (200) is integrally bonded to the mask layer (400).

12. The operating element (100, 100′, 100″) according to claim 1, wherein the cover layer (200) is integrally formed with the mask layer (400).

13. The operating element (100, 100′, 100″) according to claim 1, wherein the cover layer (200) is applied to the mask layer (400) by overmolding.

14. The operating element (100, 100′, 100″) according to claim 1,
wherein the mask layer (400) is applied to the cover layer (200) by back-injection and/or
wherein the actuating element (500) is or comprises a transparent capacitive actuating layer and/or
wherein the mask layer (400) is connected to the actuating element (500) by means of a first transparent adhesive layer (700) and/or
wherein the first transparent adhesive layer (700) comprises an optically clear adhesive film and/or
wherein the first transparent adhesive layer (700) comprises an optically clear liquid adhesive (LOCA) and/or
wherein the actuating element (500) is connected to the light source (300) by means of a second transparent adhesive layer (800) and/or
wherein the second transparent adhesive layer (800) comprises an optically clear adhesive film and/or
wherein the second transparent adhesive layer (800) comprises an optically clear liquid adhesive (LOCA) and/or
wherein the operating element (100, 100′, 100″) comprises a haptic actuator (600) configured to generate a vibration when the actuating element (500) is actuated, wherein preferably the haptic actuator (600) is arranged on a rear side of the light source (300) facing away from the cover layer (200) or on a rear side of the mask layer (400) facing away from the cover layer (200) and in particular wherein the haptic actuator (600) comprises a vibration damper, and advantageously wherein the haptic actuator (600) comprises a cylinder plunger and/or
wherein the cover layer (200) and/or the mask layer (400) comprises a polyurethane material and/or
wherein the mask layer (400) comprises a polypropylene material and/or
wherein the mask layer (400) comprises a polycarbonate material and/or
wherein the mask layer (400) comprises a polycarbonate-acrylonitrile-butadiene-styrene material and/or
wherein the operating element (100, 100′, 100″) comprises a color matching layer (930) with a gray film and/or a color film and/or
wherein the color matching layer (930) is arranged between the mask layer (400) and the light source (300), and preferably wherein the color matching layer (930) is arranged between the mask layer (400) and the first transparent adhesive layer (700) and/or
wherein the light source (300) comprises a segmented and/or spatially resolved display, wherein preferably the light source (300) comprises an LCD display and/or a TFT display and/or an OLED display and/or an LED matrix display and/or a MicroLED display and/or
wherein the operating element (100, 100′, 100″) further comprises a pressure sensor (910), which is preferably arranged on a rear side of the light source (300) facing away from the cover layer (200), and in particular wherein the pressure sensor (910) is arranged between the light source (300) and the haptic actuator (600), and advantageously wherein the pressure sensor (910) is arranged centrally below a display region of the light source (300) and/or
wherein the operating element (100, 100′, 100″) comprises a plurality of pressure sensors (910) which are arranged at corners of a display region of the light source (300).

15. The operating element (100, 100′, 100″) according to claim 1, comprising in a stacked, in particular immediately stacked, arrangement according to the following order:
the cover layer (200),
the mask layer (400),
a first transparent adhesive layer (700) by means of which the mask layer (400) is connected to the actuating element (500),
the actuating element (500), comprising or designed as a transparent capacitive actuating layer,
a second transparent adhesive layer (800) by means of which the actuating element (500) is connected to the light source (300),
the light source (300), and
a haptic actuator (600) configured to generate a vibration when the actuating element (500) is actuated.
